(19) United States
(12) Patent Application Publication
(10) Pub. No.: US 2020/0203143 A1
(43) Pub. Date: Jun. 25, 2020

(54) METHOD FOR PREPARING MULTILAYER STRUCTURE

(71) Applicant: NANYA TECHNOLOGY CORPORATION, NEW TAIPEI CITY (TW)

(72) Inventor: LIANG-PIN CHOU, TAOYUAN CITY (TW)

(21) Appl. No.: 16/368,106

(22) Filed: Mar. 28, 2019

Related U.S. Application Data
(60) Provisional application No. 62/782,049, filed on Dec. 19, 2018.

(51) Int. Cl. H01L 21/02; H01L 21/027; C23C 16/30; C23C 16/34; C23C 16/40

(52) U.S. Cl. CPC H01L 21/022; H01L 21/02181; H01L 21/02189; H01L 21/0228; H01L 23/291; C23C 16/308; C23C 16/34; C23C 16/405; H01L 21/0274

(57) ABSTRACT

A method for preparing a multilayer structure includes the following steps. A substrate having a patterned layer is disposed in a reactor. A metal precursor is introduced into the reactor, wherein the metal precursor is absorbed by the patterned layer. Excess metal precursor is purged from the reactor by pumping out the excess metal precursor. A reactant is introduced into the reactor, wherein the reactant reacts with the metal precursor to form a metal-containing layer on the patterned layer.

### PRIORITY CLAIM AND CROSS REFERENCE

This application claims the priority benefit of U.S. provisional patent application No. 62/782,049, filed on Dec. 19, 2018. The entirety of the above-mentioned patent application is hereby incorporated by reference herein and made a part of this specification.

### TECHNICAL FIELD

The present disclosure relates to a method for preparing a multilayer structure, and more particularly, to a method for preparing the multilayer structure with a purge step to remove excess precursor.

### DISCUSSION OF THE BACKGROUND

SiO₂ is known in semiconductor and photovoltaic industries to be a passivation material leading to a significant reduction in surface recombination. A high-quality SiO₂ layer can be grown by wet thermal oxidation at 900° C. or dry oxidation at 850° C. to 1000° C. under oxygen. However, such high temperatures are generally not compatible with photovoltaic device manufacturing. Therefore, alternative methods were developed such as chemical vapor deposition (CVD) of SiO₂ from TEOS with O₂. Some of the drawbacks of CVD are the difficulty in controlling layer thickness and the resulting lack of film homogeneity. Another disadvantage is the relatively poor passivation of CVD SiO₂. For these reasons, atomic layer deposition (ALD) is a preferred method for SiO₂ deposition, as it allows deposition of homogeneous layers while exhibiting good passivation properties.

Although SiO₂ has passivation capabilities, Al₂O₃ passivation is now being considered. Recent studies of Al₂O₃ deposition demonstrate that, similar to a SiO₂ layer, the Al₂O₃ layer is naturally enriched with hydrogen during deposition. Al₂O₃ contains a reasonable level of hydrogen and therefore it is not strictly necessary to add H₂ to the N₂.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a method for preparing a multilayer structure, including disposing a substrate having a patterned layer in a reactor; introducing a metal precursor into the reactor, wherein the metal precursor is absorbed by the patterned layer; purging excess metal precursor from the reactor by pumping out the excess metal precursor; and introducing a reactant into the reactor, wherein the reactant reacts with the metal precursor to form a metal-containing layer on the patterned layer.

According to some embodiments of the disclosure, the method further includes repeating the metal precursor introduction step, the excess metal precursor purge step, and the reactant introduction step until the multilayer structure has a desired thickness.

According to some embodiments of the disclosure, the reactants introduced in the reactant introduction step are the same for different repetitions of the reactant introduction step.

According to some embodiments of the disclosure, the reactants introduced in the reactant introduction step are different for different repetitions of the reactant introduction step.

According to some embodiments of the disclosure, the metal precursor includes a hafnium (Hf)-containing compound or a zirconium (Zr)-containing compound.

According to some embodiments of the disclosure, the reactant includes an oxygen-containing compound.

According to some embodiments of the disclosure, the reactant includes a nitrogen-containing compound.

According to some embodiments of the disclosure, the reactant includes a compound containing oxygen and nitrogen.

According to some embodiments of the disclosure, the metal-containing layer on the patterned layer includes a metal that is same as a metal included in the metal precursor.

According to some embodiments of the disclosure, the patterned layer is formed by exposing a photoresist layer to a patterned radiation and developing the exposed photoresist layer.

Another aspect of the present disclosure provides a method for preparing a multilayer structure, including disposing a substrate having a patterned layer in a reactor, wherein the substrate includes a carbon hard mask layer and a silicon oxynitride layer; introducing a metal precursor into the reactor, wherein the metal precursor is absorbed by the patterned layer; purging excess metal precursor from the reactor by pumping out the excess metal precursor; and introducing a reactant into the reactor, wherein the reactant reacts with the metal precursor to form a metal-containing layer on the patterned layer.

According to some embodiments of the disclosure, the method further includes repeating the metal precursor introduction step, the excess metal precursor purge step, and the reactant introduction step until the multilayer structure has a desired thickness.

According to some embodiments of the disclosure, the reactants introduced in the reactant introduction step are the same for different repetitions of the reactant introduction step.

According to some embodiments of the disclosure, the reactants introduced in the reactant introduction step are different for different repetitions of the reactant introduction step.

According to some embodiments of the disclosure, the metal precursor includes a hafnium (Hf)-containing compound or a zirconium (Zr)-containing compound.

According to some embodiments of the disclosure, the reactant includes an oxygen-containing compound.

According to some embodiments of the disclosure, the reactant includes a nitrogen-containing compound.

According to some embodiments of the disclosure, the reactant includes a compound containing oxygen and nitrogen.

According to some embodiments of the disclosure, the metal-containing layer on the patterned layer includes a metal that is same as a metal included in the metal precursor.

According to some embodiments of the disclosure, the patterned layer is formed by exposing a photoresist layer to a patterned radiation and developing the exposed photoresist layer.

Due to the utilization of pump devices to pump out excess precursor during preparation of the multilayer structure, not only is excess metal precursor purged out of the reactor, but absorption of the precursor compound by the surfaces of reaction is also enhanced, and the desired thickness of the multilayer structure can be obtained.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1 illustrates a method for preparing a multilayer structure, in accordance with some embodiments of the present disclosure;

FIG. 2 depicts a cross-sectional representation of a multilayer structure during preparation, in accordance with some embodiments of the present disclosure;

FIG. 3 depicts a cross-sectional representation of a multilayer structure during preparation, in accordance with some embodiments of the present disclosure;

FIG. 4 depicts a cross-sectional representation of a multilayer structure during preparation in a reactor, in accordance with some embodiments of the present disclosure;

FIG. 5 depicts a cross-sectional representation of a multilayer structure during preparation in a reactor, in accordance with some embodiments of the present disclosure;

FIG. 6 depicts a cross-sectional representation of a multilayer structure during preparation in a reactor, in accordance with some embodiments of the present disclosure;

FIG. 7 depicts a cross-sectional representation of a multilayer structure during preparation in a reactor, in accordance with some embodiments of the present disclosure;

FIG. 8 depicts a cross-sectional representation of a multilayer structure during preparation, in accordance with some embodiments of the present disclosure;

FIG. 9 depicts a cross-sectional representation of a multilayer structure during preparation in a reactor, in accordance with some embodiments of the present disclosure;

FIG. 10 depicts a cross-sectional representation of a multilayer structure during preparation in a reactor, in accordance with some embodiments of the present disclosure;

FIG. 11 depicts a cross-sectional representation of a multilayer structure during preparation in a reactor, in accordance with some embodiments of the present disclosure; and

FIG. 12 depicts a cross-sectional representation of a multilayer structure during preparation in a reactor, in accordance with some embodiments of the present disclosure.

### DETAILED DESCRIPTION

The following description of the disclosure accompanies drawings, which are incorporated in and constitute a part of this specification, and illustrate embodiments of the disclosure, but the disclosure is not limited to the embodiments. In addition, the following embodiments can be properly integrated to complete another embodiment.

References to “one embodiment,” “an embodiment,” “exemplary embodiment,” “other embodiments,” “another embodiment,” etc. indicate that the embodiment(s) of the disclosure so described may include a particular feature, structure, or characteristic, but not every embodiment necessarily includes the particular feature, structure, or characteristic. Further, repeated use of the phrase “in the embodiment” does not necessarily refer to the same embodiment, although it may.

The present disclosure is directed to a semiconductor device and method for manufacturing the same. In order to make the present disclosure completely comprehensible, detailed steps and structures are provided in the following description. Obviously, implementation of the present disclosure does not limit special details known by persons skilled in the art. In addition, known structures and steps are not described in detail, so as not to unnecessarily limit the present disclosure. Preferred embodiments of the present disclosure are described in detail below. However, in addition to the detailed description, the present disclosure may also be widely implemented in other embodiments. The scope of the present disclosure is not limited to the detailed description, but is defined by the claims.

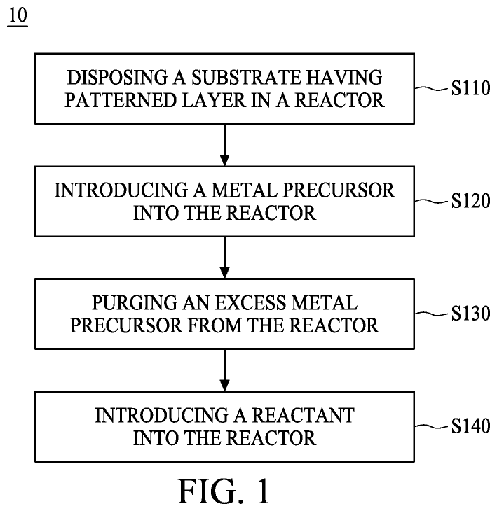

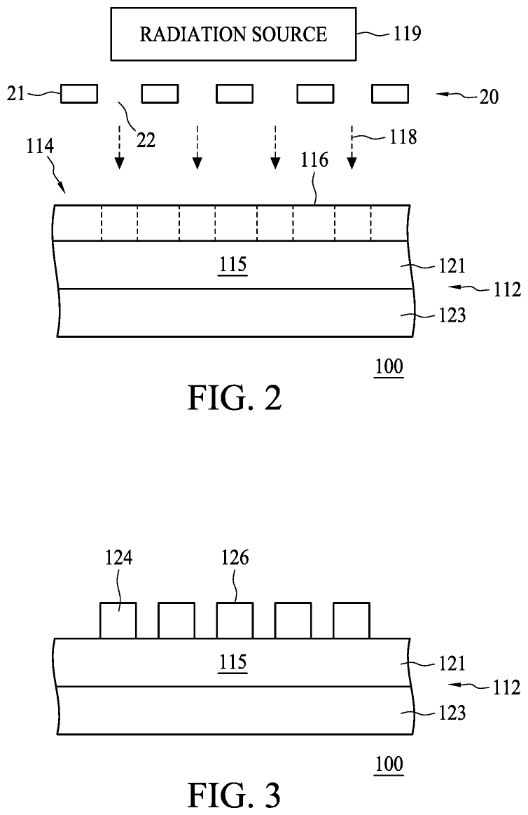

In accordance with some embodiments of the disclosure, FIG. 1 illustrates a method 10 for preparing a multilayer structure, and FIG. 2 to FIG. 7 depict cross-sectional representations of the multilayer structure during preparation. As shown in FIG. 1, a method for preparing a multilayer structure includes the following steps. A substrate having a patterned layer is disposed in a reactor (Step S110). A metal precursor is introduced into the reactor, wherein the metal precursor is absorbed by the patterned layer (Step S120). Excess metal precursor is purged from the reactor by pumping out the excess metal precursor (Step S130). A reactant is introduced into the reactor, wherein the reactant reacts with the metal precursor to form a metal-containing layer on the patterned layer (Step S140).

As shown in FIG. 2, according to some embodiments, a resist layer 114 is formed on a substrate 112 of a multilayer structure 100. The substrate 112 of the multilayer structure 100 may include one or more layers 115, which may be made from metal-containing, dielectric or semiconducting materials. The layers 115 may represent a single continuous layer, a segmented layer, or different active or passive features, such as transistors, integrated circuits, photovoltaic components, display components, or the like, which are located in the substrate 112 or on the surface of the substrate 112. In some embodiments, the layers 115 may include a carbon hard mask layer 121 and a silicon oxynitride layer 123, for example. Typically, the resist layer 114 is deposited over the layer 115 which is already on the substrate 112. However, the resist layer 14 may also be formed directly on the substrate 112. The resist layer 114 is patterned to form a patterned layer 124 having resist features 126 which may serve as etch-resistant features to transfer a pattern to the underlying layer 115 on the substrate 112 by etching through the exposed portions of the layer 115 that lie between the resist features 126.

In some embodiments, the resist layer 114 is a photoresist layer 116, which may be made of a radiation-sensitive material which is not limited to photon- or light-sensitive materials, and may be light-sensitive, electron-sensitive, X-ray sensitive or another radiation-sensitive material. In some embodiments, the photoresist layer 116 is a positive photoresist or negative photoresist which is sensitive to light. A positive resist is one in which the portion of the photoresist that is exposed to light becomes soluble to a photoresist developer, and the portion that is unexposed remains insoluble to a photoresist developer. A negative resist is one in which the portion of the photoresist that is exposed to light becomes insoluble to the photoresist developer, and the unexposed portion is dissolved by the photoresist developer. The photoresist layer 116 may be made of a photoresist material, such as Polymethylmethacrylate (PMMA), PolyMethylGlutarimide (PMGI), Phenol formaldehyde resin, diazonaphthoquinone (DNQ) and novolac resin, or SU-8, which is an epoxy-based negative photoresist. In some embodiments, the photoresist layer 116 may be formed with a thickness from about 5 nm to about 500 nm, for example.

In some embodiments, the resist layer 114 may be applied as a liquid by dip coating or spin-coating. In the spin-coating process, the liquid resist is dispensed over the surface of the substrate 112, while the substrate 112 is rapidly spun until it becomes dry. Spin-coating processes may be conducted at spinning speeds of around 2000 to about 6500 rpm for about 15 to about 30 seconds. Resist coating is followed by a soft bake process which heats the spin-coated resist layer to evaporate the solvent from the spun-on resist, improve the adhesion of the resist to the substrate 112, or even anneal the resist layer 114 to reduce shear stresses which are introduced during spin-coating. Soft baking can be performed in an oven, such as a convection, infrared, or hot plate oven. The typical temperature range for soft baking is from about 80 to about 100° C. In one example, dry films may also be applied, such as polymer films, which are radiation sensitive. Dry films may or may not need to be baked or cured depending on the nature of the film.

In some embodiments, as shown in FIG. 2, the resist layer 114, including, for example, the photoresist layer 116, may then be exposed to a patterned radiation 118 provided by a radiation source 119 through a mask 20, for example. The mask 20 may be a plate 21 with holes 22 (as shown) or transparent portions (not shown) that correspond to a pattern which allows radiation 118 to selectively permeate through portions of the mask to form a radiation pattern of intersecting lines or arcs. The masks 20 may be fabricated by methods known by ones skilled in the art.

In some embodiments, the photoresist layer 116 may be made of SU-8, which is a viscous polymer that can be spun or spread with a thickness ranging from 0.1 micrometers to 2 millimeters and processed with standard contact lithography. The photoresist layer 116 may be used to pattern the resist features 126 shown in FIG. 3 which have a high aspect ratio (the ratio of the height to the width of the feature) that is equal to or greater than 20. In this example, the radiation source 119 provides ultraviolet light having a wavelength between 170 and 195 nm.

In some embodiments, the photoresist layer 116 may include an electron-sensitive material, and the radiation source 119 may be an electron beam source. Electron beam lithography typically relies on photoresist materials which are specified for electron-beam exposure, and electron beam lithography techniques and materials known in the art may be used. In some embodiments, the photoresist layer 116 may be made of a light-sensitive material such as diazonaphthoquinone (DNQ). The radiation source 119 provides ultraviolet light having wavelengths of less than 300 nm, for example, about 248 nm, such as a mercury lamp. The photoresist layer 116 including DNQ may strongly absorb light having wavelengths from about 300 nm to about 450 nm. In some embodiments, the photoresist layer 116 may be made of a positive photoresist based on a mixture of DNQ and novolac resin (a phenol formaldehyde resin). A suitable radiation source 119 for such photoresist may a mercury vapor lamp, set to provide light including I, G and H-lines from the mercury vapor lamp.

As shown in FIG. 2 and FIG. 3, in some embodiments, after the resist layer 114 is exposed to radiation 118 to create a pattern in the resist layer 114, the exposed resist layer 114 may be developed to form a patterned layer 124 having a plurality of resist features 126 that may be spaced apart from one another. In one example of the development step, the photoresist layer 116 exposed to radiation is treated with a liquid developer to set in the exposed and unexposed portions of the photoresist layer 116 to form the patterned layer 124. The liquid developer initiates chemical reactions in the exposed resist layer 114 wherein unexposed or exposed portions of the photoresist layer 116 dissolve in the developer depending on whether the resist is a positive or negative resist. Suitable developers include dilute solutions of a base, such as sodium or potassium carbonate. For example, the developer may be a 1% solution of sodium carbonate monohydrate (Na₂CO₃.H2O), or potassium carbonate (K₂CO₃), sodium hydroxide, or a mixture thereof. Automated pH-controlled feed-and-bleed developing may also be used with pH levels set to about 10.5. The resist layer 114 may also be developed by immersion or by spraying the selected developer. After development, the substrate 112 with the resist features 126 is rinsed and dried to ensure that development will not continue after the developer has been removed from the substrate 112.

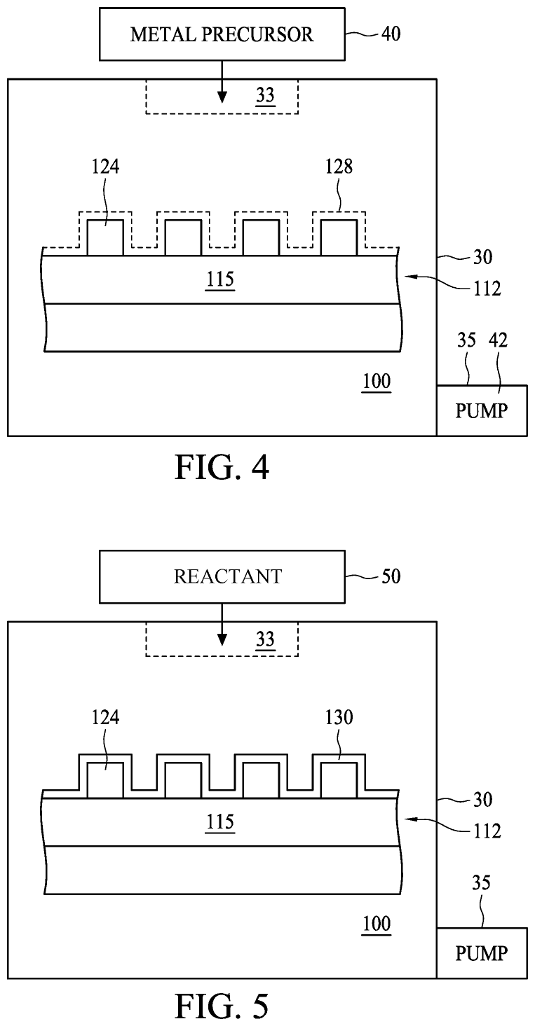

In some embodiments, as shown in FIG. 4, the substrate 112 having the patterned layer 124 with the resist features 126 is next disposed in a reactor 30 to prepare the multilayer structure 100. A metal precursor 40 may be introduced into the reactor 30 containing the substrate 112. The metal precursor 40 may include a hafnium (Hf)-containing compound or a zirconium (Zr)-containing compound, for example. The metal precursor 40 may be introduced into the reactor 30 after being processed in a processing zone 33 where the metal precursor 40 may be heated and vaporized, if necessary, according to application. The metal precursor 40 may be transported to the processing zone 33 via a carrier gas, for example. After introduction into the reactor 30, the metal precursor 40, which may include the Hf-containing compound or the Zr-containing compound, is absorbed by the patterned layer 124 to form a first precursor absorption layer 128, as shown in FIG. 4. Excess metal precursor 42 is purged by a pump device 35 pumping out the excess metal precursor 42 from the reactor 30. It should be noted that those skilled in the art will appreciate that the temperature, pressure, carrier gas flow rate, and pumping duration in the reactor 30 can be adjusted to control the amount of the metal precursor 40 introduced and pumped out according to application.

In some embodiments, as shown in FIG. 5, a reactant 50 is next introduced into the reactor 30 after being processed in the processing zone 33 at a temperature and pressure suitable for the application. The reactant 50 may require a carrier gas for transport to the processing zone 33. Those skilled in the art will appreciate that the temperature, pressure, and carrier gas flow rate in the reactor 30 can be adjusted to control the amount of reactant 50 to be introduced. The reactant 50 may include an oxygen-containing compound such as oxygen (O₂) or ozone (O₃). For example, in some embodiments, the oxygen-containing reactant 50 may react with the metal precursor 40 to form a first metal-containing layer 130 on the patterned layer 124. The first metal-containing layer 130 may include a metal that is same as a metal included in the metal precursor 40.

In some embodiments, the reactant 50 may include a nitrogen-containing compound, such as nitrogen (N₂), hydrazine (NH₂NH₂), ammonia (NH₃), its alkyl or aryl derivatives, or a mixture thereof. In other embodiments, the reactant 50 may include a compound containing oxygen and nitrogen, such as NO, NO₂, N₂O, N₂O₄, N₂O₅, or a mixture thereof.

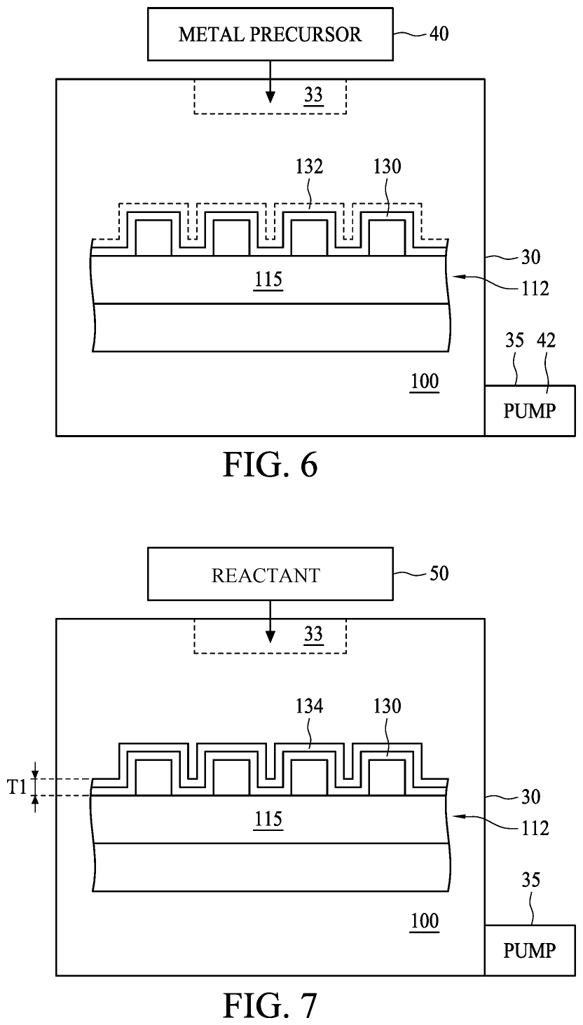

In some embodiments, as shown in FIG. 6 and FIG. 7, the metal precursor introduction step, the excess metal precursor purge step, and the reactant introduction step depicted in FIG. 4 and FIG. 5 may be repeated until the multilayer structure 100 has a desired thickness T1. With reference to FIG. 6, the metal precursor 40 may be introduced again into the reactor 30 containing the substrate 112. The metal precursor 40 may include the hafnium (Hf)-containing compound or the zirconium (Zr)-containing compound of FIG. 4, for example. The metal precursor 40 may be introduced into the reactor 30 after being processed in a processing zone 33 where the metal precursor 40 may be heated and vaporized, if necessary, according to application. The metal precursor 40 may be transported to the processing zone 33 via a carrier gas, for example. After introduction into the reactor 30, the metal precursor 40, which may include the Hf-containing compound or the Zr-containing compound, is absorbed by the first metal-containing layer 130 to form a second precursor absorption layer 132, as shown in FIG. 6. The excess metal precursor 42 is purged again by the pump device 35 pumping out the excess metal precursor 42 from the reactor 30. It should be noted that those skilled in the art will appreciate that the temperature, pressure, carrier gas flow rate, and pumping duration in the reactor 30 can be adjusted in different cycles to control the amount of the metal precursor 40 introduced and pumped out according to application, so as to obtain the desired thickness T1 of the multilayer structure 100.

With reference to FIG. 7, in some embodiments, the reactant 50 is again introduced into the reactor 30 after being processed in the processing zone 33 at a temperature and pressure suitable for the application. The reactant 50 may require a carrier gas for transport to the processing zone 33. Those skilled in the art will appreciate that the temperature, pressure, and carrier gas flow rate in the reactor 30 can be adjusted in different cycles to control the amount of reactant 50 to be introduced. The reactant 50 may include the oxygen-containing compound such as oxygen (O₂) or ozone (O₃) of FIG. 5, for example. The oxygen-containing reactant 50 reacts with the metal precursor 40 to form a second metal-containing layer 134 on the first metal-containing layer 130. In some embodiments, the second metal-containing layer 134 may include a metal that is same as a metal included in the metal precursor 40. Accordingly, by using the pump device 35 to pump out excess precursor during preparation of the multilayer structure 100, not only is the excess metal precursor 42 purged out of the reactor 30, but absorption of the precursor compound by the surfaces of reaction is also enhanced, and the desired thickness T1 of the multilayer structure 100 can be obtained.

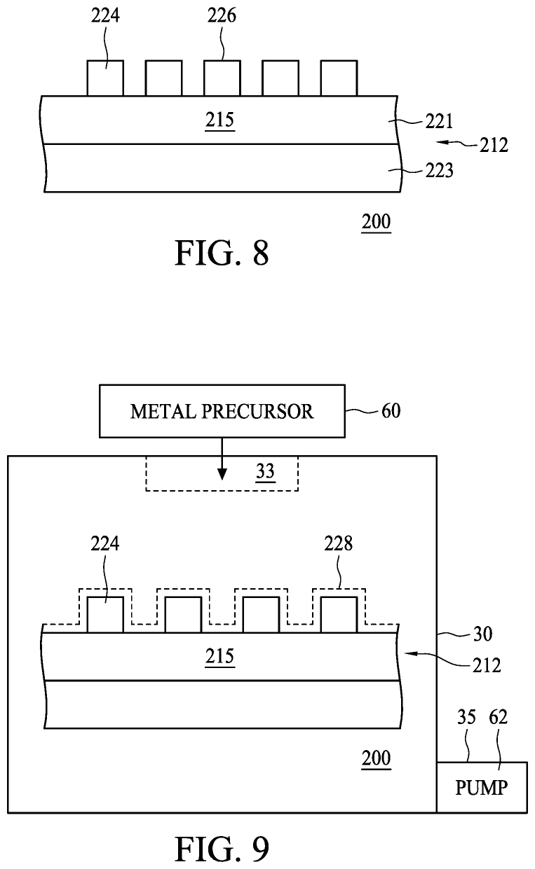

It should be noted that, although the reactants used in the reactant introduction step for preparing the multilayer structure 100 may be the same for different repetitions of the reactant introduction step, the disclosure is not limited thereto. In some embodiments, the reactants used in the reactant introduction step for preparing the multilayer structure may be different for different repetitions of the reactant introduction step, as shown by the preparation of a multilayer structure 200 depicted in the cross-sectional representations of FIG. 8 to FIG. 12.

As shown in FIG. 8, according to some embodiments, a substrate 212 of the multilayer structure 200 may include one or more layers 215, which may be made from metal-containing, dielectric or semiconducting materials. The layers 215 may represent a single continuous layer, a segmented layer, or different active or passive features, such as transistors, integrated circuits, photovoltaic components, display components, or the like, which are located in the substrate 212 or on the surface of the substrate 212. In some embodiments, the layers 215 may include a carbon hard mask layer 221 and a silicon oxynitride layer 223, for example. Similar to the patterned layer 124 of FIG. 3, a patterned layer 224 having resist features 226 is formed, wherein the resist features 226 may serve as etch-resistant features to transfer a pattern to the underlying layer 215 on the substrate 212 by etching through the exposed portions of the layer 215 that lie between the resist features 226. However, it should be noted that the patterned layer 224 may also be formed by different variations of the process shown in FIG. 2.

In some embodiments, as shown in FIG. 9, the substrate 212 having the patterned layer 224 with the resist features 226 is next disposed in the reactor 30 to prepare the multilayer structure 200. A metal precursor 60 may be introduced into the reactor 30 containing the substrate 212. The metal precursor 60 may include a hafnium (Hf)-containing compound or a zirconium (Zr)-containing compound, for example. The metal precursor 60 may be introduced into the reactor 30 after being processed in a processing zone 33, where the metal precursor 60 may be heated and vaporized if necessary, according to application. The metal precursor 60 may be transported to the processing zone 33 via a carrier gas, for example. After being introduced into the reactor 30, the metal precursor 60, which may include the Hf-containing compound or Zr-containing compound, is absorbed by the patterned layer 224 to form a third precursor absorption layer 228, as shown in FIG. 9. Excess metal precursor 62 is purged by the pump device 35 pumping out the excess metal precursor 62 from the reactor 30. It should be noted that those skilled in the art will appreciate that the temperature, pressure, carrier gas flow rate, and pumping duration in the reactor 30 can be adjusted to control the amount of the metal precursor 60 introduced and pumped out according to application.

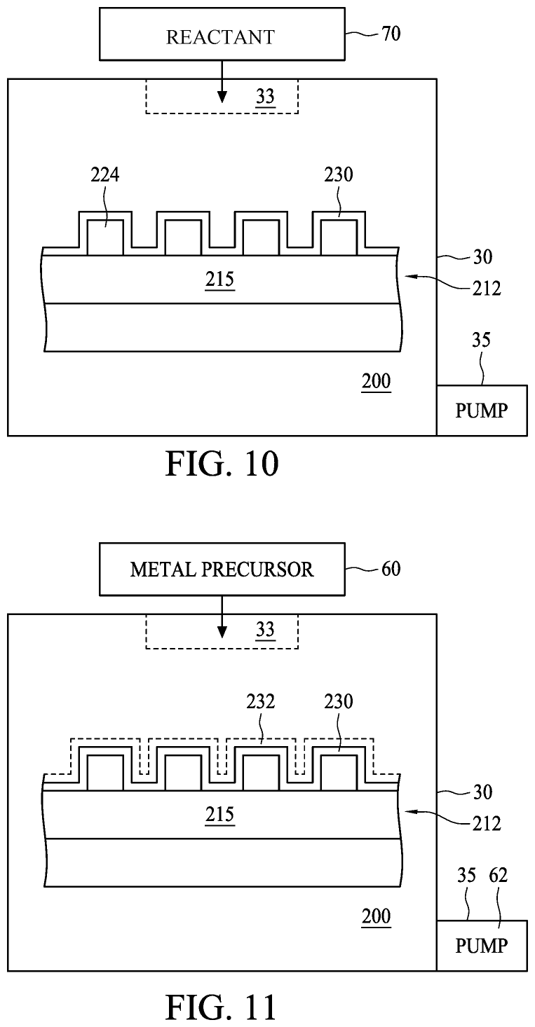

In some embodiments, as shown in FIG. 10, a reactant 70 is next introduced into the reactor 30 after being processed in the processing zone 33 at a temperature and pressure suitable for the application. The reactant 70 may require a carrier gas for transport to the processing zone 33. Those skilled in the art will appreciate that the temperature, pressure, and carrier gas flow rate in the reactor 30 can be adjusted to control the amount of reactant 70 to be introduced. The reactant 70 may include an oxygen-containing compound such as oxygen (O₂) or ozone (O₃). For example, in some embodiments, the oxygen-containing reactant 70 may react with the metal precursor 60 to form a third metal-containing layer 230 on the patterned layer 224. The third metal-containing layer 230 may include a metal that is same as a metal included in the metal precursor 60.

In some embodiments, the reactant 70 may include a nitrogen-containing compound, such as nitrogen (N₂), hydrazine (NH₂NH₂), ammonia (NH₃), its alkyl or aryl derivatives, or a mixture thereof. In other embodiments, the reactant 70 may include a compound containing oxygen and nitrogen, such as NO, NO₂, N₂O, N₂O₄, N₂O₅, or a mixture thereof.

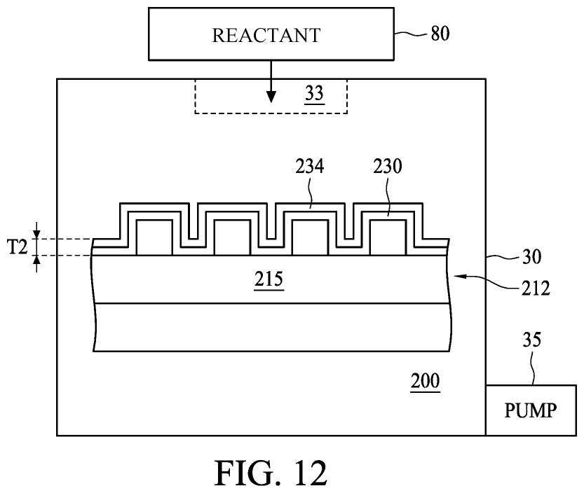

In some embodiments, as shown in FIG. 11 and FIG. 12, the metal precursor introduction step, the excess metal precursor purge step, and the reactant introduction step depicted in FIG. 9 and FIG. 10 may be repeated until the multilayer structure 200 has a desired thickness T2. With reference to FIG. 11, the metal precursor 60 may be introduced again into the reactor 30 containing the substrate 212. The metal precursor 60 may include the hafnium (Hf)-containing compound or the zirconium (Zr)-containing compound of FIG. 9, for example. The metal precursor 60 may be introduced into the reactor 30 after being processed in a processing zone 33, where the metal precursor 60 may be heated and vaporized if necessary, according to application. The metal precursor 60 may be transported to the processing zone 33 via a carrier gas, for example. After introduction into the reactor 30, the metal precursor 60, which may include the Hf-containing compound or Zr-containing compound, is absorbed by the third metal-containing layer 230 to form a fourth precursor absorption layer 232, as shown in FIG. 11. The excess metal precursor 62 is purged again by the pump device 35 pumping out the excess metal precursor 62 from the reactor 30. It should be noted that those skilled in the art will appreciate that the temperature, pressure, carrier gas flow rate, and pumping duration in the reactor 30 can be adjusted in different cycles to control the amount of the metal precursor 60 introduced and pumped out according to application, so as to obtain the desired thickness T2 of the multilayer structure 200.

With reference to FIG. 12, in some embodiments, a reactant 80 is introduced into the reactor 30 after being processed in the processing zone 33 at a temperature and pressure suitable for the application. In such embodiments, the reactants 70 and 80 used in the reactant introduction step are different for different repetitions of the reactant introduction step. The reactant 80 may require a carrier gas for transport to the processing zone 33. Those skilled in the art will appreciate that the temperature, pressure, and carrier gas flow rate in the reactor 30 can be adjusted in different cycles to control the amount of reactant 80 to be introduced. The reactant 80 may include oxygen-containing compound such as oxygen (O₂) or ozone (O₃). For example, in some embodiments, the oxygen-containing reactant 80 reacts with the metal precursor 60 to form a fourth metal-containing layer 234 on the third metal-containing layer 230. In some embodiments, the fourth metal-containing layer 234 may include a metal that is same as a metal included in the metal precursor 60. Accordingly, by using the pump device 35 to pump out excess precursor during preparation of the multilayer structure 100, not only is the excess metal precursor purged out of the reactor 30, but absorption of the precursor compound by the surfaces of reaction is also enhanced, and the desired thickness T2 of the multilayer structure 200 can be obtained.

It should be noted that, in some embodiments, the reactant 80 may include a nitrogen-containing compound, such as nitrogen (N₂), hydrazine (NH₂NH₂), ammonia (NH₃), its alkyl or aryl derivatives, or a mixture thereof. In other embodiments, the reactant 80 may include a compound containing oxygen and nitrogen, such as NO, NO₂, N₂O, N₂O₄, N₂O₅, or a mixture thereof.

Furthermore, in accordance with some embodiments, the precursors 40 and 60 as well as the reactants 50, 70, and 80 used to prepare the multilayer structures 100 and 200 may be individually fed to a vaporizer in the processing zone 33, for example, where they are each individually vaporized before introduction into the reactor 30. The terms “each” and “individually” herein represent one or more precursors and reactants chosen to be used as the precursors 40 and 60 and the reactants 50, 70, and 80. Prior to vaporization, each of the precursors 40 and 60, as well as reactants 50, 70, and 80, may optionally be mixed with one or more solvents in the processing zone 33. The solvents may be selected from toluene, ethyl benzene, xylene, mesitylene, decane, dodecane, octane, hexane, pentane, other suitable solvents, and mixtures thereof. Moreover, the precursors 40 and 60 may also be chosen from bis(diethylamino)silane (BDEAS), tris(dimethylamino)silane (3DMAS), tetrakis(dimethylamino)silane (4DMAS), tetrakis(ethylmethylamino)hafnium, other suitable amino-metal precursors, other suitable halogenated precursors, and mixtures thereof. Some possible carrier gasses that can be used, if necessary, may include, but are not limited to, Ar, He, N₂, other suitable carrier gasses, and mixtures thereof.

In some embodiments, the pump device 35 of the reactor 30 may include an exhaust (not shown) to remove spent process gas and byproducts from the reactor 30 and maintain a predetermined pressure of process gas in the processing zone 33. The pump device 35 may include pump channels that receive spent process gas from the processing zone 33, exhaust ports, throttle valves, and exhaust pumps to control the pressure of process gasses in the reactor 30. The pump device 35 may include one or more of a turbo-molecular pump, cryogenic pump, roughing pump, and combination-function pumps that have more than one function. The reactor 30 may also include an inlet port or tube (not shown) through a wall of the reactor 30 to deliver a purging gas into the reactor 30. The purging gas may typically flow upward from the inlet port past the support plates of the multilayer structure 100 and 200 and to an annular pumping channel The purging gas may be used to protect the surfaces of the support plates and other reactor 30 components from undesired deposition during the processing. The purging gas may also be used to affect the flow of process gas in a desirable manner.

In accordance with some embodiments of the disclosure, examples of the substrates 112 and 212 may include, without limitation, silicon substrates, silica substrates, silicon nitride substrates, silicon oxynitride substrates, metal substrates, metal nitride substrates, tungsten substrates, or combinations thereof. Moreover, in some embodiments, the substrates 112 and 212 may include noble metals (e.g., platinum, palladium, rhodium, or gold) or tungsten.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

1. A method for preparing a multilayer structure, comprising:
disposing a substrate having a patterned layer and an exposed portion which is not covered by the patterned layer in a reactor;
introducing a metal precursor into the reactor to form a precursor absorption layer on the patterned layer and the exposed portion of the substrate;
purging an excess metal precursor which does not react with the metal precursor from the reactor by pumping out the excess metal precursor; and
introducing a reactant into the reactor, wherein the reactant reacts with the metal precursor of the precursor absorption layer to form a metal-containing layer on the patterned layer and the exposed portion of the substrate.

2. The method of claim 1, further comprising repeating the metal precursor introduction step, the excess metal precursor purge step, and the reactant introduction step until the multilayer structure has a desired thickness.

3. The method of claim 2, wherein the reactants introduced in the reactant introduction step are the same for each repetition of the reactant introduction step.

4. The method of claim 2, wherein the reactants introduced in the reactant introduction step are different for repetitions of the reactant introduction step.

5. The method of claim 1, wherein the metal precursor comprises a hafnium (Hf)-containing compound or a zirconium (Zr)-containing compound.

6. The method of claim 1, wherein the reactant comprises an oxygen-containing compound.

7. The method of claim 1, wherein the reactant comprises a nitrogen-containing compound.

8. The method of claim 1, wherein the reactant comprises a compound containing oxygen and nitrogen.

9. The method of claim 1, wherein the metal-containing layer on the patterned layer comprises a metal that is same as the metal included in the metal precursor.

10. The method of claim 1, further comprising:
forming a photoresist layer on the substrate;
exposing the photoresist layer to a patterned radiation; and
developing the exposed photoresist layer to form the patterned layer.

11. A method for preparing a multilayer structure, comprising:
disposing a substrate having a patterned layer and an exposed portion which is not covered by the patterned layer in a reactor, wherein the substrate comprises a carbon hard mask layer and a silicon oxynitride layer located beneath the carbon hard mask layer;
introducing a metal precursor into the reactor to form a precursor absorption layer on the patterned layer and the exposed portion;
purging an excess metal precursor which does not react with the metal precursor from the reactor by pumping out the excess metal precursor; and
introducing a reactant into the reactor, wherein the reactant reacts with the metal precursor of the precursor absorption layer to form a metal-containing layer on the patterned layer and the exposed portion of the substrate.

12. The method of claim 11, further comprising repeating the metal precursor introduction step, the excess metal precursor purge step, and the reactant introduction step until the multilayer structure has a desired thickness.

13. The method of claim 12, wherein the reactants introduced in the reactant introduction step are the same for different repetitions of the reactant introduction step.

14. The method of claim 12, wherein the reactants introduced in the reactant introduction step are different for repetitions of the reactant introduction step.

15. The method of claim 11, wherein the metal precursor comprises a hafnium (Hf)-containing compound or a zirconium (Zr)-containing compound.

16. The method of claim 11, wherein the reactant comprises an oxygen-containing compound.

17. The method of claim 11, wherein the reactant comprises a nitrogen-containing compound.

18. The method of claim 11, wherein the reactant comprises a compound containing oxygen and nitrogen.

19. The method of claim 11, wherein the metal-containing layer on the patterned layer comprises a metal that is same as a metal included in the metal precursor.

20. The method of claim 11, further comprising:
forming a photoresist layer on the substrate;
exposing the photoresist layer to a patterned radiation; and
developing the exposed photoresist layer to form the patterned layer.
